(19) United States
(12) Patent Application Publication
(10) Pub. No.: US 2008/0153182 A1
(43) Pub. Date: Jun. 26, 2008

(54) METHOD AND SYSTEM TO MEASURE AND COMPENSATE FOR SUBSTRATE WARPAGE DURING THERMAL PROCESSING

(75) Inventors: Harald Herchen, Los Altos, CA (US); Brian C. Lue, Mountain View, CA (US); Kim Vellore, San Jose, CA (US); Erica Renee Porras, Los Gatos, CA (US); James Yi Liu, Mountain View, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SOKUDO CO., LTD, Kyoto (JP)

(21) Appl. No.: 11/777,929

(22) Filed: Jul. 13, 2007

Related U.S. Application Data
(60) Provisional application No. 60/871,189, filed on Dec. 21, 2006.

(51) Int. Cl. H01L 21/324

(52) U.S. Cl. 438/10; 432/45; 257/E21.324

(57) ABSTRACT

A method of performing a thermal process using a bake plate of a track lithography tool. The bake plate includes a plurality of heater zones. The method includes providing a first drive signal to a first electrode in electrical communication with a process surface of the bake plate. The first electrode is associated with a first heater zone of the plurality of heater zones and each of the plurality of heater zones is adapted to receive a control voltage. The method also includes moving a semiconductor substrate toward the process surface of the bake plate, receiving a first response signal from the first electrode, processing the first response signal to determine a first capacitance value associated with a first gap between the first electrode and a first portion of the semiconductor substrate, and providing a measurement signal related to the first capacitance value.

### CROSS-REFERENCES TO RELATED APPLICATIONS

The present application claims benefit under 35 U.S.C. § 119(e) of U.S. Provisional Patent Application No. 60/871,189, filed Dec. 21, 2006, entitled “Method and System to Measure and Compensate for Substrate Warpage During Thermal Processing,” which is incorporated herein by reference in its entirety.

### BACKGROUND OF THE INVENTION

The present invention relates generally to the field of substrate processing equipment. More particularly, the present invention relates to a method and apparatus for controlling a bake plate of a semiconductor processing apparatus. Merely by way of example, the method and apparatus of the present invention determine and compensate for substrate shape during thermal processing of the substrate in an thermal processing chamber of a track lithography tool. The method and apparatus can be applied to other processing devices for semiconductor processing equipment utilized in other processing chambers.

Modern integrated circuits contain millions of individual elements that are formed by patterning the materials, such as silicon, metal and dielectric layers, that make up the integrated circuit to sizes that are small fractions of a micrometer. The technique used throughout the industry for forming such patterns is photolithography. A typical photolithography process sequence generally includes depositing one or more uniform photoresist (resist) layers on the surface of a substrate, drying and curing the deposited layers, patterning the substrate by exposing the photoresist layer to radiation that is suitable for modifying the exposed layer and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (which are sometimes referred to herein as stations) dedicated to performing the various tasks associated with pre- and post-lithography processing. There are typically both wet and dry processing chambers within track lithography tools. Wet chambers include coat and/or develop bowls, while dry chambers include thermal control units that house bake and/or chill plates. Track lithography tools also frequently include one or more pod/cassette mounting devices, such as an industry standard FOUP (front opening unified pod), to receive substrates from and return substrates to the clean room, multiple substrate transfer robots to transfer substrates between the various stations of the track tool and an interface that allows the tool to be operatively coupled to a lithography exposure tool in order to transfer substrates into the exposure tool and to receive substrates after they have been processed within the exposure tool.

Over the years there has been a strong push within the semiconductor industry to shrink the size of semiconductor devices. The reduced feature sizes have caused the industry's tolerance to process variability to shrink, which in turn, has resulted in semiconductor manufacturing specifications having more stringent requirements for process uniformity and repeatability. An important factor in minimizing process variability during track lithography processing sequences is to ensure that substrate processing is performed uniformly as a function of wafer position. For example, during bake processes, it is desirable to provide uniform thermal treatment across the substrate. Because processed wafers are generally characterized by wafer bowing, achieving uniform thermal treatment is hindered by the different air gaps between the substrate and the bake plate.

Thus, there is a need in the art for improved methods and systems for measuring and compensating for wafer warpage during thermal processing operations.

### SUMMARY OF THE INVENTION

According to embodiments of the present invention, techniques related to the field of substrate processing equipment are provided. More particularly, the present invention relates to a method and apparatus for controlling a bake plate of a semiconductor processing apparatus. Merely by way of example, the method and apparatus of the present invention determine and compensate for substrate shape during thermal processing of the substrate in an thermal processing chamber of a track lithography tool. The method and apparatus can be applied to other processing devices for semiconductor processing equipment utilized in other processing chambers.

According to an embodiment of the present invention, a method of performing a thermal process using a bake plate of a track lithography tool is provided. The bake plate includes a plurality of heater zones. The method includes providing a first drive signal to a first electrode in electrical communication with a process surface of the bake plate. The first electrode is associated with a first heater zone of the plurality of heater zones and each of the plurality of heater zones is adapted to receive a control voltage. The method also includes moving a semiconductor substrate toward the process surface of the bake plate, receiving a first response signal from the first electrode, and processing the first response signal to determine a first capacitance value associated with a first gap between the first electrode and a first portion of the semiconductor substrate. The method further includes providing a measurement signal related to the first capacitance value.

In a particular embodiment, the method further includes modifying a first control voltage for a first heater zone of the plurality of heater zones. The first control voltage is based, in part, on the measurement signal. In another particular embodiment, the method additionally includes providing a second drive signal to the first electrode. The second drive signal is based, in part, on the measurement signal and is operative to generate an electrostatic chucking force between the semiconductor substrate and the first electrode.

In another embodiment of the present invention, a bake plate system for a track lithography tool is provided. The bake plate system includes a processing system including a heater controller and a processor. The processor is adapted to output a plurality of first drive signals in a first frequency range, receive a plurality of response signals related to the plurality of first drive signals, and output a plurality of second drive signals in a second frequency range. The bake plate system also includes a bake plate including a process surface and a lower surface opposing the process surface. The bake plate also includes a plurality of independent heating elements in thermal contact with the process surface. Each of the plurality of independent heating elements is adapted to receive a control signal from the heater controller. The bake plate further includes a plurality of electrodes coupled to the process surface. Each of the plurality of electrodes is adapted to receive one of the plurality of first drive signals from the processor and one of the plurality of second drive signals from the processor. The bake plate additionally includes a plurality of mechanical stops disposed on the process surface.

Many benefits are achieved by way of the present invention over conventional techniques. For example, embodiments of the present invention provide information on substrate bending modes during wafer placement. Additionally, embodiments provide for local adjustment of the heat transfer rate as a function of substrate position, thereby compensating for gap variations. Moreover, some embodiments utilize an integrated electrostatic chuck to dynamically reduce gap variations during thermal processing steps. Depending upon the embodiment, one or more of these benefits, as well as other benefits, may be achieved. These and other benefits will be described in more detail throughout the present specification and more particularly below in conjunction with the following drawings.

### BRIEF DESCRIPTION OF THE DRAWINGS

FIG. 1 is a simplified plan view of a track lithography tool according to an embodiment of the present invention;

FIG. 2 is a simplified cut-away perspective view of a thermal unit according to an embodiment of the present invention;

FIG. 3 is a perspective view of a cross-section of a bake station according to an embodiment of the present invention;

FIG. 4 is a simplified representative view of a conventional multi-zone bake plate;

FIG. 5A is a simplified plan view of a bake plate with integrated capacitive sensors according to an embodiment of the present invention;

FIG. 5B is a simplified schematic diagram of a thermal control system according to an embodiment of the present invention;

FIG. 6 is a simplified flowchart illustrating a method of measuring and compensating for substrate warpage according to an embodiment of the present invention;

FIG. 7 is a simplified flowchart illustrating a method of operating an electrostatic chuck according to an embodiment of the present invention;

FIG. 8 is a simplified flowchart illustrating the method of determining the substrate bending mode according to an embodiment of the present invention; and

FIG. 9 is a plot of wafer distance versus time obtained using an embodiment of the present invention.

### DETAILED DESCRIPTION OF SPECIFIC EMBODIMENTS

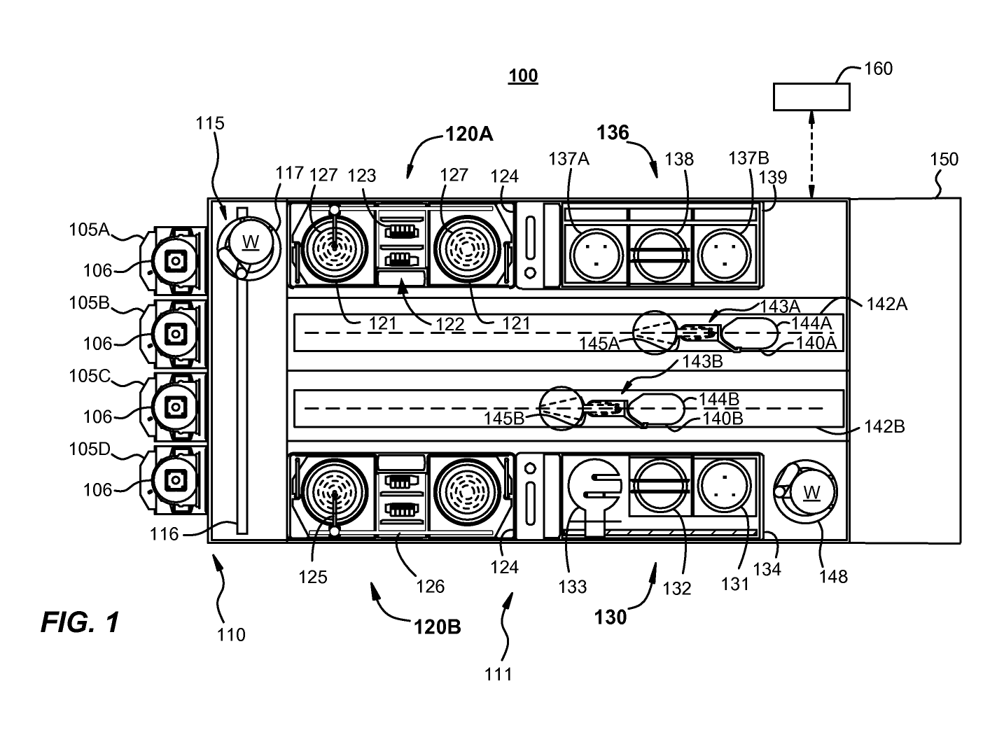

FIG. 1 is a plan view of an embodiment of a track lithography tool in which the embodiments of the present invention may be used. As illustrated in FIG. 1, the track lithography tool contains a front end module 110 (sometimes referred to as a factory interface) and a process module 111. In other embodiments, the track lithography tool includes a rear module (not shown), which is sometimes referred to as a scanner interface. Front end module 110 generally contains one or more pod assemblies or FOUPS (e.g., items 105A-D) and a front end robot assembly 115 including a horizontal motion assembly 116 and a front end robot 117. The front end module 110 may also include front end processing racks (not shown). The one or more pod assemblies 105A-D are generally adapted to accept one or more cassettes 106 that may contain one or more substrates or wafers that are to be processed in the track lithography tool. The front end module 110 may also contain one or more pass-through positions (not shown) to link the front end module 110 and the process module 111.

Process module 111 generally contains a number of processing racks 120A, 120B, 130, and 136. As illustrated in FIG. 1, processing racks 120A and 120B each include a coater/developer module with shared dispense 124. A coater/developer module with shared dispense 124 includes two coat bowls 121 positioned on opposing sides of a shared dispense bank 122, which contains a number of dispense nozzles 123 providing processing fluids (e.g., bottom anti-reflection coating (BARC) liquid, resist, developer, and the like) to a wafer mounted on a substrate support 127 located in the coat bowl 121. In the embodiment illustrated in FIG. 1, a nozzle positioning member 125 sliding along a track 126 is able to pick up a dispense nozzle 123 from the shared dispense bank 122 and position the selected dispense nozzle over the wafer for dispense operations. Coat bowls with dedicated dispense banks are provided in alternative embodiments.

Processing rack 130 includes an integrated thermal unit 134 including a bake plate 131, a chill plate 132 and a shuttle 133. The bake plate 131 and the chill plate 132 are utilized in heat treatment operations including post exposure bake (PEB), post-resist bake, and the like. In some embodiments the shuttle 133, which moves wafers in the x-direction between the bake plate 131 and the chill plate 132, is chilled to provide for initial cooling of a wafer after removal from the bake plate 131 and prior to placement on the chill plate 132. Moreover, in other embodiments shuttle 133 is adapted to move in the z-direction, enabling the use of bake and chill plates at different z-heights. Processing rack 136 includes an integrated bake and chill unit 139, with two bake plates 137A and 137B served by a single chill plate 138.

One or more robot assemblies (robots) 140 are adapted to access the front-end module 110, the various processing modules or chambers retained in the processing racks 120A, 120B, 130, and 136, and the scanner 150. By transferring substrates between these various components, a desired processing sequence can be performed on the substrates. The two robots 140 illustrated in FIG. 1 are configured in a parallel processing configuration and travel in the x-direction along horizontal motion assembly 142. Utilizing a mast structure (not shown), the robots 140 are also adapted to move orthogonal to the transfer direction. Utilizing one or more of three directional motion capabilities, robots 140 are able to place wafers in and transfer wafers between the various processing chambers retained in the processing racks that are aligned along the transfer direction.

Referring to FIG. 1, the first robot assembly 140A and the second robot assembly 140B are adapted to transfer substrates to the various processing chambers contained in the processing racks 120A, 120B, 130, and 136. In one embodiment, to perform the process of transferring substrates in the track lithography tool, robot assembly 140A and robot assembly 140B are similarly configured and include at least one horizontal motion assembly 142, a vertical motion assembly 144, and a robot hardware assembly 143 supporting a robot blade 145. Robot assemblies 140 are in communication with a controller 160 that controls the system. In the embodiment illustrated in FIG. 1, a rear robot assembly 148 is also provided.

The scanner 150 is a lithographic projection apparatus used, for example, in the manufacture of integrated circuits. The scanner 150 exposes a photosensitive material that was deposited on the substrate in the cluster tool to some form of radiation to generate a circuit pattern corresponding to an individual layer of the integrated circuit device to be formed on the substrate surface.

Each of the processing racks 120A, 120B, 130, and 136 contain multiple processing modules in a vertically stacked arrangement. That is, each of the processing racks may contain multiple stacked coater/developer modules with shared dispense 124, multiple stacked integrated thermal units 134, multiple stacked integrated bake and chill units 139, or other modules that are adapted to perform the various processing steps required of a track photolithography tool. As examples, coater/developer modules with shared dispense 124 may be used to deposit a bottom antireflective coating (BARC) and/or deposit and/or develop photoresist layers. Integrated thermal units 134 and integrated bake and chill units 139 may perform bake and chill operations associated with hardening BARC and/or photoresist layers after application or exposure.

In one embodiment, controller 160 is used to control all of the components and processes performed in the cluster tool. The controller 160 is generally adapted to communicate with the scanner 150, monitor and control aspects of the processes performed in the cluster tool, and is adapted to control all aspects of the complete substrate processing sequence. The controller 160, which is typically a microprocessor-based controller, is configured to receive inputs from a user and/or various sensors in one of the processing chambers and appropriately control the processing chamber components in accordance with the various inputs and software instructions retained in the controller's memory. The controller 160 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 160 determines which tasks are performable in the processing chambers. Preferably, the program is software readable by the controller 160 and includes instructions to monitor and control the process based on defined rules and input data.

It is to be understood that embodiments of the invention are not limited to use with a track lithography tool such as that depicted in FIG. 1, but may be used in any track lithography tool including the many different tool configurations described in U.S. patent application Ser. Nos. 11/112,281 entitled “Cluster Tool Architecture for Processing a Substrate” filed on Apr. 22, 2005, and 11/315,984 entitled “Cartesian Robot Cluster Tool Architecture” filed on Dec. 22, 2005, both of which are hereby incorporated by reference for all purposes. In addition, embodiments of the invention may be used in other semiconductor processing equipment.

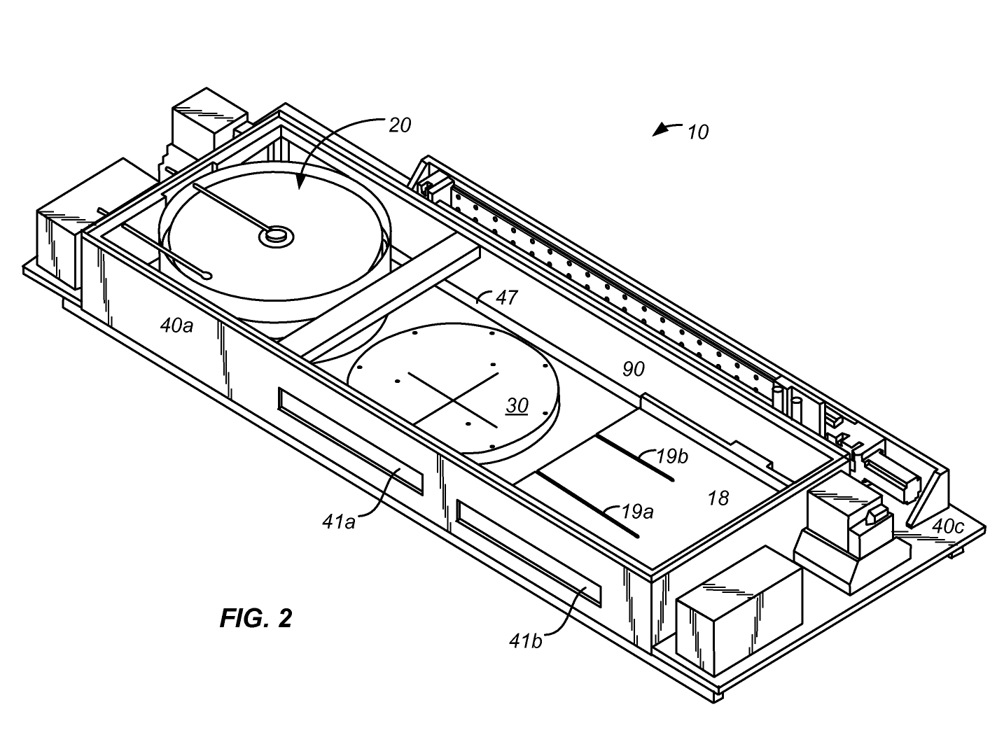

FIG. 2 is a simplified cut-away perspective view of a thermal unit according to an embodiment of the present invention. As illustrated in FIG. 2, the thermal unit 10 is shown in a cut-away view in which the top cover (not shown) is removed. The thermal unit 10 is serviced by a central robot through wafer transfer slots 41a and 41b in surface 40a. Generally, substrates enter the thermal unit through wafer transfer slot 41b and are placed on the shuttle 18, also referred to as a transfer shuttle. The shuttle delivers the substrate to the chill plate 30 and the clam shell enclosure 20 as appropriate to the particular thermal processes being performed on the substrate. The thermal unit 10 includes a shuttle 18, a chill plate 30, and clam shell enclosure 20 in which substrates are baked during portions of the lithography process. Lift pin slots 19a and 19b are provided in shuttle 18 to enable lift pins supporting the wafer to pass through the body of the shuttle. Also visible is a space 47 between rear support piece 90 of the housing and a bottom piece 40c. Space 47 extends along much of the length of thermal unit 10 to allow shuttle 18 to transfer wafers between bake and chill plates in the thermal unit.

Clam shell enclosure 20 contains a bake plate (not shown). In some embodiments, the bake plate is a multi-zone heater plate adapted to provide controlled heating to various portions of a substrate mounted on the bake plate. Additionally, some embodiments provide for a single-zone or multi-zone lid for the clam shell enclosure 20. Additional description of thermal units provided according to embodiments of the present invention is provided in co-pending and commonly assigned U.S. patent application Ser. No. 11/174,988, filed on Jul. 5, 2005 and hereby incorporated by reference in its entirety for all purposes.

Embodiments of the present invention are utilized in temperature controlled processes performed utilizing bake plates used for post-application-bake (PAB) and/or post-exposure-bake (PEB) processes. Uses are not limited to these processes as the cooling of temperature control structures are included within the scope of embodiments of the present invention. These other temperature control structures include chill plates, develop plates, and the like. One of ordinary skill in the art would recognize many variations, modifications, and alternatives.

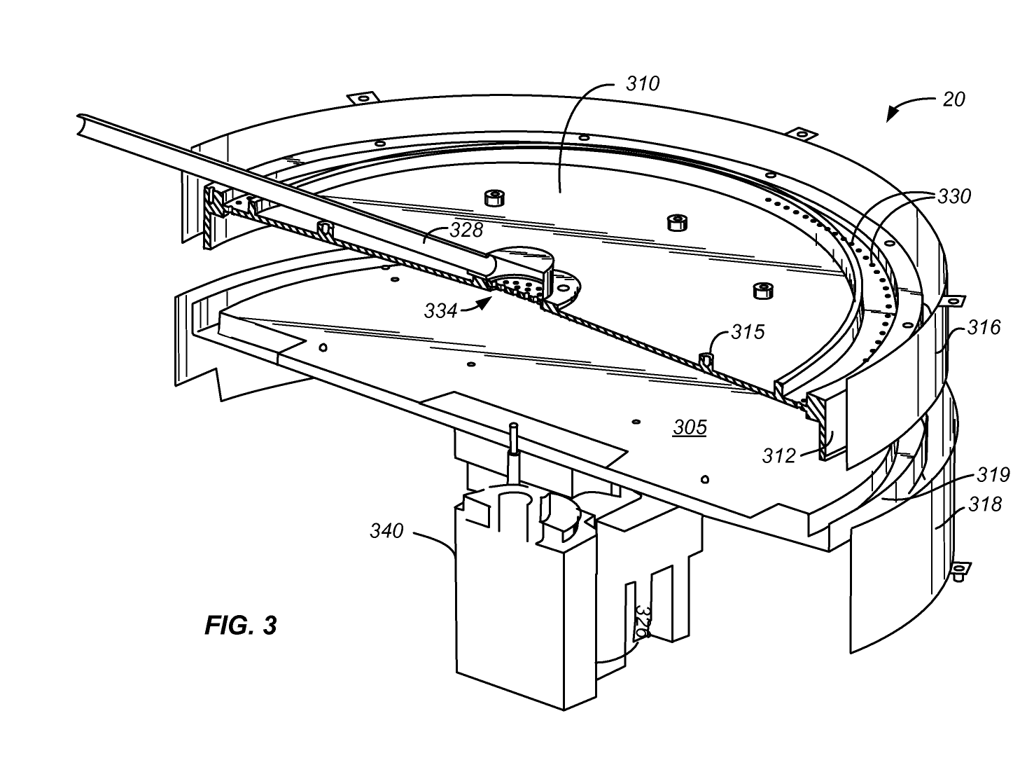

FIG. 3 is a perspective view of a cross-section of a bake station according to an embodiment of the present invention. As illustrated in FIG. 3, bake station 20 includes three separate isothermal heating elements: bake plate 305, top heat plate 310, and side heat plate 312, each of which is manufactured from a material exhibiting high heat conductivity, such as aluminum or other appropriate material. Each plate 305, 310, and 312 has a heating element, for example resistive heating elements, embedded within the plate. Bake plate 305 is generally fabricated from aluminum and the thickness of the bake plate is typically on the order of 10 mm. Bake station 20 also includes side, top and bottom heat shields 316 and 318, respectively, as well as a bottom cup 319 that surrounds bake plate 305. In an embodiment, each of heat shields 316, 318, and cup 319 are made from aluminum. A lid (not shown) is attached to top heat plate 310 by eight screws through threaded holes 315.

Bake plate 305 is operatively coupled to a motorized lift 340 so that the bake plate can be raised into the clam shell enclosure and lowered into a wafer receiving position. Typically, wafers are heated on bake plate 305 when it is raised to a baking position. When in the baking position, cup 319 encircles a bottom portion of side heat plate 312 forming a clam shell arrangement that helps confine heat generated by bake plate 305 within an inner cavity formed by the bake plate and the enclosure. In one embodiment, the upper surface of bake plate 305 includes 8 wafer pocket buttons and 17 proximity pins. Also, in one embodiment bake plate 305 includes a plurality of vacuum ports and can be operatively coupled to a vacuum chuck to secure a wafer to the bake plate during the baking process. In another embodiment, the bake plate includes an electrostatic chuck to secure the wafer to the bake plate during the baking process.

Gas is initially introduced into bake station 20 at an annular gas manifold 326 that encircles the outer portion of top heat plate 310. Gas manifold 326 includes numerous small gas inlets 330 (128 inlets in one embodiment) that allow gas to flow from manifold 326. After flowing through the station, gas exits bake station 20 through exhaust manifold 334 and gas outlet line 328.

Bake plate 305 heats a wafer according to a particular thermal recipe. One component of the thermal recipe is typically a set point temperature at which the bake plate is set to heat the wafer. During the baking process, embodiments of the present invention measure the gap between the wafer and the bake plate at a number of locations across the bake plate. Based on these gap measurements, one or more zones of the bake plate can be adjusted to ensure uniform heating of the substrate. Additional description of the methods and systems utilized to measure and compensate for wafer warpage are provided throughout the present specification and more particularly below.

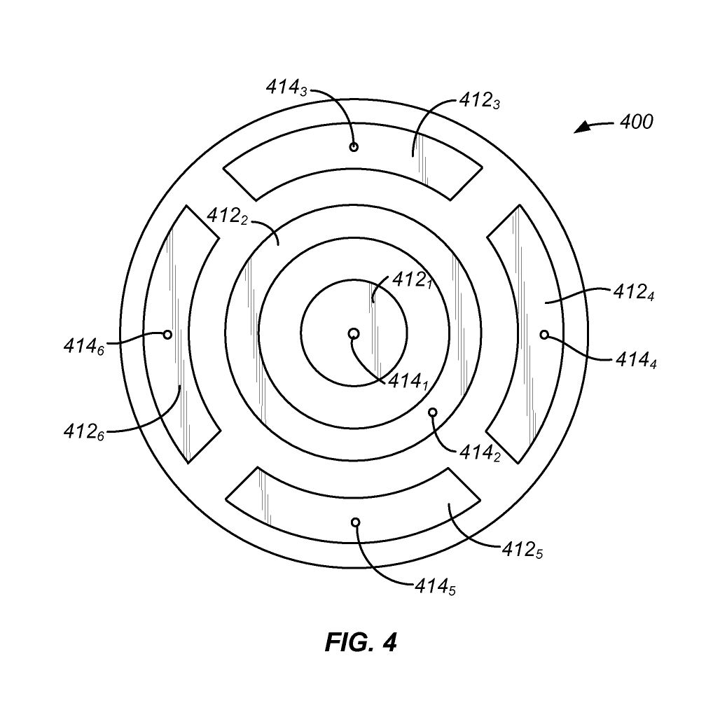

FIG. 4 is a simplified representative view of a conventional multi-zone bake plate. As illustrated in FIG. 4, the bake plate includes six different electrically independently heating zones. Referring to FIG. 1, bake plate 400 includes six independent heater zones 4412₁-412₆ along with a corresponding number of temperature sensors 414₁-414₆, one for each of the heater zones 412₁-412₆.

In some conventional systems utilized to estimate wafer warpage profile during thermal processing, the bake plate temperature profiles are monitored within each of the bake plate zones. Because the various vertical air gaps between the warped wafer and the multi-zone bake plate are characterized by different heat transfer rates, the air gaps can be extracted from temperature readings obtained in each of the zones. Thus, in these conventional techniques, using first-principles thermal modeling and system identification techniques, an estimate of the profile of the warped wafer can be obtained. A drawback of using these conventional techniques is that the time required to determine the wafer warpage is a function of the thermal transfer rates, typically resulting in measurement times on the order of several to tens of seconds. In other words, the variations in thermal transfer rates across the bake plate, which are computed using temperature readings from thermal sensors in the bake plate, are only determined slowly, placing limits on the temporal response of such a measurement system.

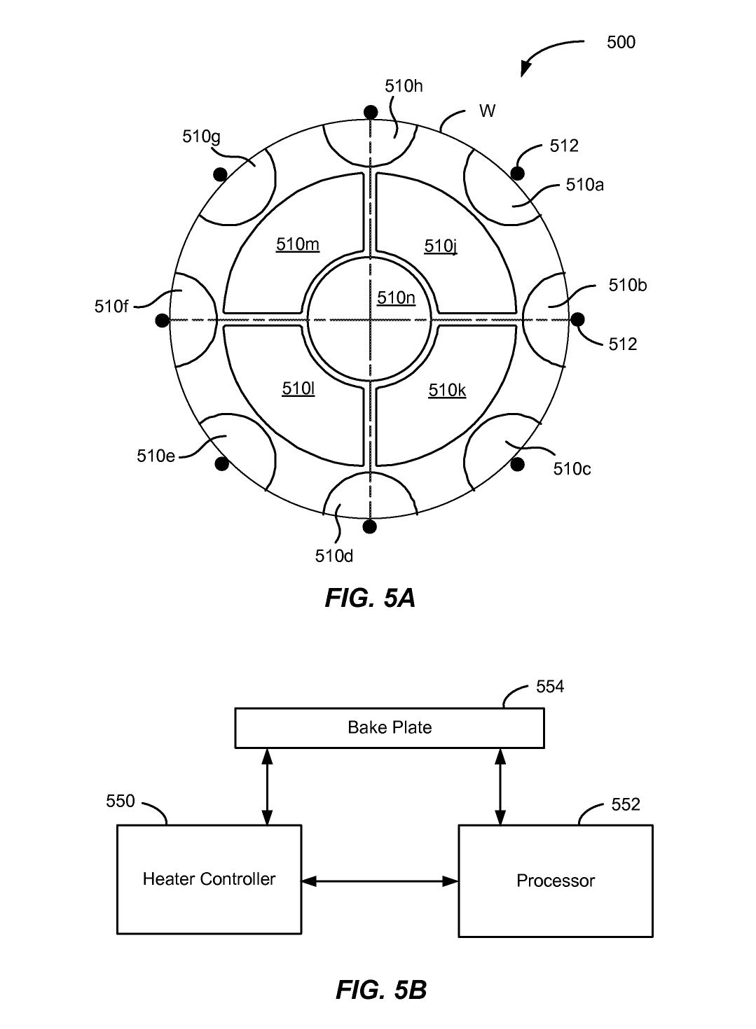

FIG. 5A is a simplified plan view of a bake plate with integrated capacitive sensors according to an embodiment of the present invention. Referring to FIG. 5A, the bake plate with integrated capacitive sensors 500 includes a number of electrodes 510 adjacent the mechanical stops 512, which form a wafer pocket for wafer W. The mechanical stops or protrusions (bosses) 512 extend from the surface of the bake plate and provide a mechanical limiting function to arrest horizontal sliding motion of the substrate. Generally, the mechanical stops are tapered and can be made from any appropriate material, such as a thermoplastic material, that exhibit strong fatigue resistance and thermal stability. In one embodiment, mechanical stops 512 are made from polyetheretherketone, which is also known as PEEK. In the embodiment illustrated in FIG. 5A, eight mechanical stops 512 are utilized to form the wafer pocket, which has an inner diameter equal to the wafer diameter.

A number of electrodes 510 are provided on the bake plate and utilized to provide capacitance measurements as described more fully below. In the embodiment illustrated in FIG. 5A, eight electrodes 510a-510h are provided in association with the eight mechanical stops 512. The electrodes 510 are in electrical communication with control electronics (not shown) used to provide electrical signals to the electrodes. The electrodes 510 are typically deposited or otherwise formed on the upper surface of the bake plate, which is fabricated from a thermally conductive material. By way of example, bake plates may be fabricated from aluminum nitride, stainless steel, copper, graphite, aluminum, ceramics, combinations of these, and the like. As will be evident to one of skill in the art, electrical isolation is provided as appropriate between the electrodes 510 and other portions of the bake plate, which may be electrically conductive as well as thermally conductive.

Although the electrodes 510 and mechanical stops 512 are illustrated as separate elements in FIG. 5A, this is not required by embodiments the present invention. In other embodiments, the electrodes 510 and mechanical stops 512 are integrated into a single element that serves both purposes. One of ordinary skill in the art would recognize many variations, modifications, and alternatives.

As a substrate is placed on the bake plate, the electrodes 510 capacitively couple to the substrate as the substrate settles onto the bake plate. The spatial positioning of the electrodes 510a-510h is selected to position each of the electrodes adjacent one of the mechanical stops 512. Thus, as the substrate settles onto the bake plate, the electrodes 510a-510h are positioned to provide capacitive coupling data for eight peripheral positions of the substrate. In addition to electrodes 510a-510h, which are located to align with peripheral portions of the substrate, additional electrodes 510j-510n are provided at interior portions of the bake plate. Accordingly, electrodes 510j-510n are located to align with interior portions of the substrate.

In an embodiment, the electrodes 510 are formed using heater elements present in the bake plate 500. For example, the electrodes 510 as illustrated in FIG. 5A may be defined by resistive heating elements present either on the top surface of the bake plate 500 or at an internal layer of the bake plate 500. As described more fully below, in these embodiments, capacitively coupled measurement signals are provided in a first frequency band and control signals for the heater elements are provided in a second frequency band. Thus, the single electrical structure of the heater element is utilized to provide control signals for the heater and capacitance coupling measurement signals utilized to determine wafer shape.

In yet other embodiments, multiple elements are utilized to form the electrodes 510 and the heater elements. For example, in some applications, the heater elements are embedded in a dielectric material, such as a Kapton® polyimide film. In these applications, electrical connections for the electrodes and heater elements are provided separately as they pass through the dielectric layers as will be evident to one of skill in the art.

FIG. 5B is a simplified schematic diagram of a thermal control system according to an embodiment of the present invention. The thermal control system, which may be referred to as a bake plate system for a track lithography tool, includes a processing system having a heater controller 550 and a processor 552. The processing system is adapted to output a plurality of first drive signals in a first frequency range, receive a plurality of response signals related to the plurality of first drive signals, and output a plurality of second drive signals in a second frequency range. These signals are provided to and received from the bake plate 554.

As described previously, the bake plate may include a process surface and a lower surface opposing the process surface and a plurality of independent heating elements in thermal contact with the process surface. Each of the plurality of independent heating elements is adapted to receive a control signal from the heater controller. The bake plate may also include a plurality of electrodes coupled to the process surface. Each of the plurality of electrodes is adapted to receive one of the plurality of first drive signals from the processor and one of the plurality of second drive signals from the processor. The bake plate may further include a plurality of mechanical stops disposed on the process surface.

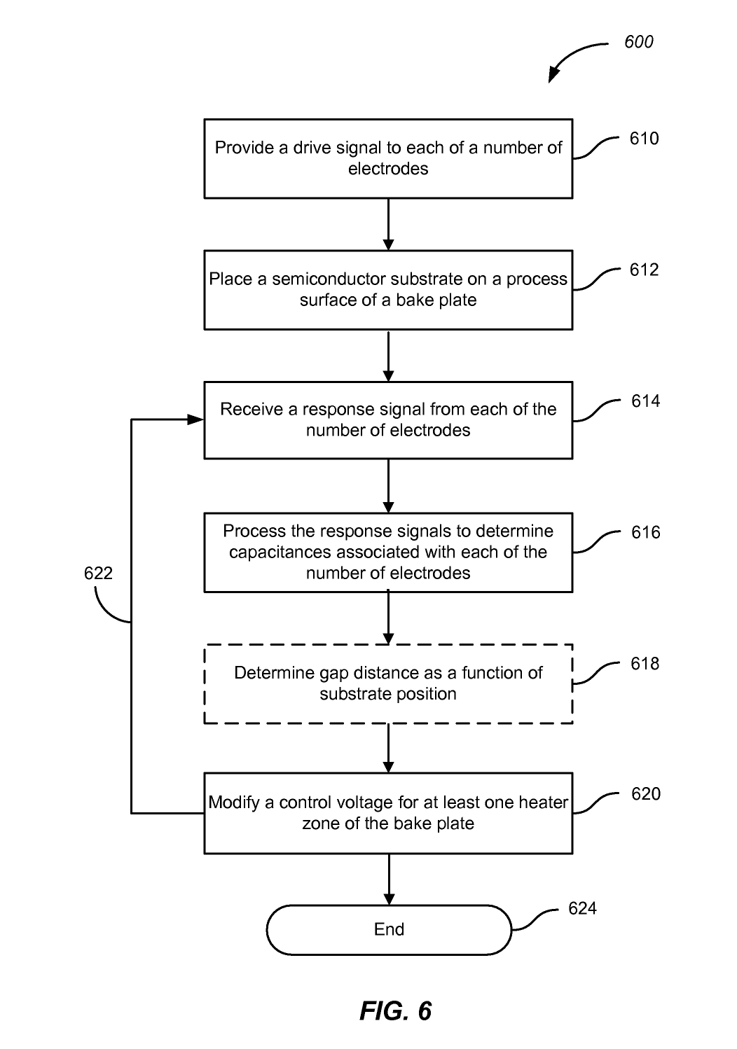

FIG. 6 is a simplified flowchart illustrating a method of measuring and compensating for substrate warpage according to an embodiment of the present invention. The method 600 includes providing a drive signal to each of a number of electrodes (610). Generally, the drive signal is an oscillatory electrical signal of a predetermined frequency. In an embodiment, the predetermined frequency is greater than 0.1 kHz. In other embodiments, the predetermined frequency ranges from about 0.1 kHz to about 100 kHz. Of course, the particular frequency of the drive signal will depend on the particular application, including electrode geometry and the like.

A semiconductor substrate is placed on a process surface of the bake plate (612) and a response signal from each of the number of electrodes is received (614). As the substrate is placed on the bake plate, the decreasing distance between the substrate and the bake plate will result in a variation in the capacitive coupling between the substrate and the electrodes 510. As a result, the response signal from each of the electrodes will be a function of the local separation between the particular electrode and the portion of the substrate above that particular electrode. The response signals are processed to determine capacitances associated with each of the electrodes (616).

Generally, the response signal is modulated in phase and amplitude by the proximity of the wafer to the particular electrode. Thus, a phase locked loop can be utilized to rapidly measure changes in the capacitance by computing phase and amplitude differences between the drive signal and the response signal. In optional step 618, the gap between each of the electrodes and the portion of the substrate opposite each of the electrodes is determined. Generally, this computation converts the measured capacitance values into local gap distances. Thus, as the wafer approaches the bake plate, vertical wafer to electrode distances are measured utilizing embodiments the present invention. A benefit provided by embodiments of the present invention is the fast response time achievable using capacitively coupled electrodes. Conventional approaches, which utilize resistive thermal devices (RTDs) buried in the bake plate, provide much slower response times. As described more fully below, embodiments the present invention provide for repetition of a number of the steps illustrated in FIG. 6 as the wafer is placed on the bake plate. Such operations utilizing rapid response times are not available utilizing conventional techniques characterized by slower response times.

A control voltage provided to at least one of the heater zones of the bake plate is modified (620) and steps 614 through 620 are repeated (622) until variations in the gap distance stabilize at a predetermined level. In an embodiment, heater zones associated with portions of the substrate characterized by a larger gap distance, and therefore lower thermal conductivity, receive control signals that result in additional local heat generation. As result, based on the measurements of the wafer shape, modifications are made in the thermal profile of the bake plate as a function of position, compensating for wafer warpage. In some embodiments, a model-based controller is used to adjust the various heater zones to compensate for the local heat transfer rate, which depends on the inferred local gap distance. Adjustments in the control signals provided to the heater zones compensates for deviations from the nominal gap distance, thereby providing better control of the transient as well as steady state thermal input to the substrate. As will be evident to one of skill in the art, improved thermal control translates into improved critical dimension (CD) control, which is of significant benefit to semiconductor fabrication facilities. As discussed above, in comparison with conventional techniques that provide a slow response time as a result of the use of RTDs, the methods provided herein provide rapid response times, enabling rapid modifications of the local heat transfer rate. Once the wafer is positioned on the bake plate, method 600 is terminated at step 624.

It should be appreciated that the specific steps illustrated in FIG. 6 provide a particular method of measuring and compensating for substrate warpage according to an embodiment of the present invention. Other sequences of steps may also be performed according to alternative embodiments. For example, alternative embodiments of the present invention may perform the steps outlined above in a different order. Moreover, the individual steps illustrated in FIG. 6 may include multiple sub-steps that may be performed in various sequences as appropriate to the individual step. Furthermore, additional steps may be added or removed depending on the particular applications. One of ordinary skill in the art would recognize many variations, modifications, and alternatives.

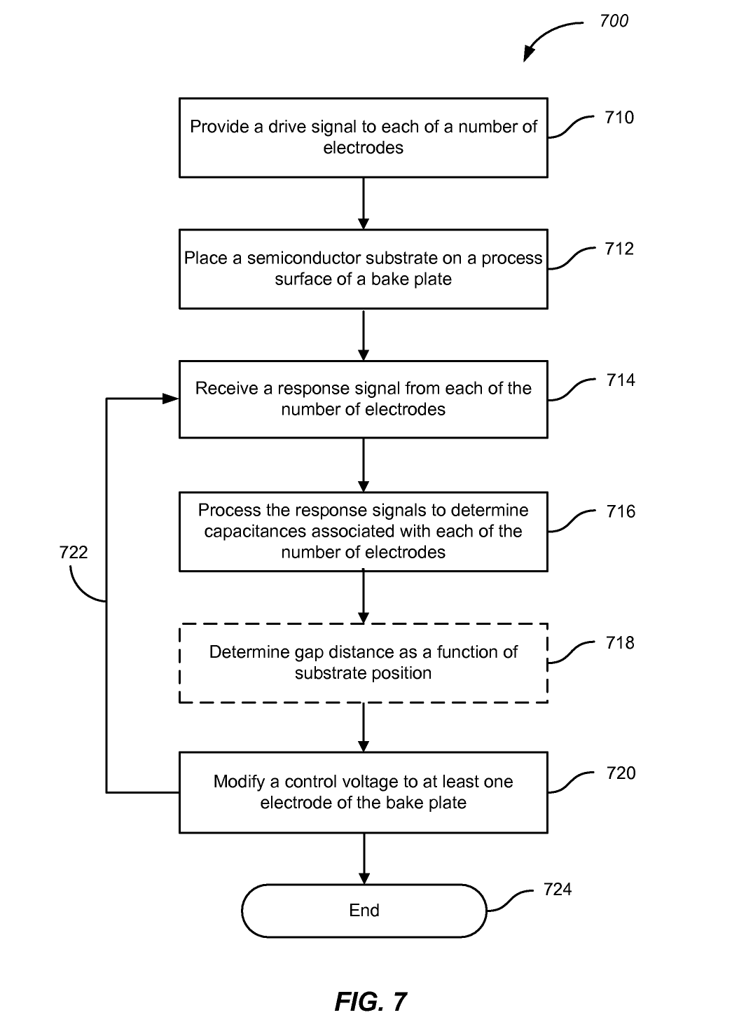

FIG. 7 is a simplified flowchart illustrating a method of operating an electrostatic chuck according to an embodiment of the present invention. As illustrated in FIG. 7, method 700 shares a number of common steps with method 600. Method 700 includes providing a drive signal to each of the electrodes on the bake plate (710), and placing a semiconductor substrate on the process surface of the bake plate (712). As the semiconductor substrate is placed on the bake plate, capacitive coupling between the substrate and the electrodes results in a response signal which is received by a processor (714). The response signals from each of the electrodes are processed (716) to determine capacitances associated with each of the electrodes. Optionally, the local gap distance is determined as a function of substrate position (718) and a control voltage applied to at least one of the electrodes is modified (720). Modification of the control voltage applied to particular electrodes in step 720 results in an increase or decrease in the electrostatic chucking force applied to the portion of the substrate adjacent to the particular electrode. Steps 714 through 720 are repeated (722) as the wafer settles on to the bake plate, with method 700 terminating at step 724.

Thus, embodiments of the present invention combine the functions of a capacitance sensor and an electrostatic chuck electrode in the electrodes 510 illustrated in FIG. 5. The frequency of the drive signal, as discussed above, is characterized by a first frequency range, which is high enough so that the drive signal does not interfere with the control voltages utilized to generate electrostatic chucking force. In practice, the electrodes receive a composite signal comprising the control voltages for the electrostatic chuck as well as the high frequency drive signals for the capacitive measurements. As the wafer settles onto the bake plate, local capacitance measurements are utilized to modify the local electrostatic chucking force in a real-time control loop, which then drive changes in the local capacitance measurements. Therefore, the electrostatic chucking forces increases at portions of the wafer with a larger gap distance, decreasing the gap distance, which allows the electrostatic chucking force to be decreased. As the substrate is flattened in contact with the proximity pins, a minimum electrostatic chucking voltage is used to maintain the uniform gap between the substrate and the bake plate as a function of position. As a result, wafer bending between the proximity pins is minimized, resulting in uniform heat transfer between the bake plate and the substrate. The rapid response times characteristic of the capacitively coupled electrodes enables operation in a real-time control loop in which the capacitance measurements are utilized to modify the chucking voltage, which modifies the capacitance measurements, etc.

In the embodiment illustrated in FIG. 7, modification of the control voltages provided to the heater zones (e.g., step 620) is not utilized. By using the electrostatic chuck to flatten the substrate, variations in thermal transfer to account for gap distance variations are not generally needed. However, embodiments of the present invention are not limited to the use of the methods illustrated in either FIG. 6 or FIG. 7 as alternatives. In some embodiments, combinations of the steps illustrated in FIGS. 6 and 7 are utilized as appropriate to the particular application. One of ordinary skill in the art would recognize many variations, modifications, and alternatives.

It should be appreciated that the specific steps illustrated in FIG. 7 provide a particular method of operating an electrostatic chuck according to an embodiment of the present invention. Other sequences of steps may also be performed according to alternative embodiments. For example, alternative embodiments of the present invention may perform the steps outlined above in a different order. Moreover, the individual steps illustrated in FIG. 7 may include multiple sub-steps that may be performed in various sequences as appropriate to the individual step. Furthermore, additional steps may be added or removed depending on the particular applications. One of ordinary skill in the art would recognize many variations, modifications, and alternatives.

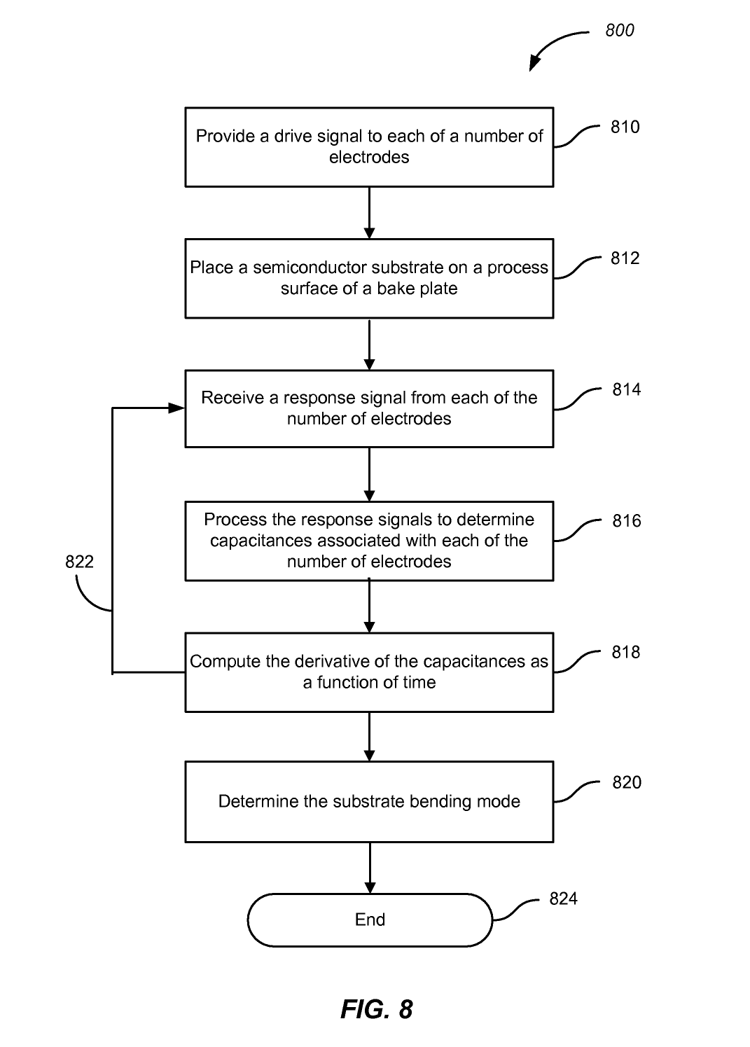

FIG. 8 is a simplified flowchart illustrating the method of determining the substrate bending mode according to an embodiment of the present invention. Method 800 includes providing a drive signal to each of the electrodes on the bake plate (810), and placing a semiconductor substrate on the process surface of the bake plate (812). As the semiconductor substrate is placed on the bake plate, capacitive coupling between the substrate and the electrodes results in a response signal which is received by a processor (814). The response signals from each of the electrodes are processed (816) to determine capacitances associated with each of the electrodes. As the substrate settles onto the bake plate, the derivative of the capacitance values are computed as a function of time. This computation is equivalent to computing the derivative of local gap distances between the substrate and the electrodes and function of time. The derivatives are computed for each of the electrodes 510, providing data on the rate at which the various portions of the substrate approach the bake plate during settling.

Utilizing the derivative curves computed in step 818, the substrate bending mode is determined (820). Depending on the bending mode which characterizes the substrate (e.g., flat, concave downwards, concave upwards, saddle shaped, and the like), the rate at which the various portions of the substrate approach the bake plate and the phase shift between the derivative curves for the various electrodes will vary. For example if the substrate is bowed concave upwards, air beneath the substrate will escape from beneath the substrate more quickly than if the substrate is bowed concave downwards. As a result, in the former case, wafer settling will occur more rapidly than in the latter case. Thus, utilizing the peripheral electrodes, the substrate bending mode can be determined utilizing the derivative curves.

As discussed above, the rate at which the capacitively coupled electrodes provide measurement data contrasts with conventional techniques that utilize RTDs. Information related to the bending mode of the substrate is obtained utilizing some embodiments of the present invention in times on the order of milliseconds, not multiple seconds. Additionally, angular orientation data may be obtained using embodiments of the present invention.

Generally, semiconductor substrates provide a limited number of bending modes, for example, concave, saddle, and the like. For some of these bending modes, for example, a saddle-shaped mode, the bending mode lacks radial symmetry. For these modes, the angular position of the wafer can be determined as the wafer is placed and settles on the bake plate provided herein. The distance from bake plate surface to the substrate is determined as a function of position and the orientation is computed for these non-radially symmetric bending modes.

The determination of the substrate bending mode in step 820 may also utilize a phase shift between the derivative curves. For example, utilizing the interior electrodes 510j-510n, for a substrate bowed concave upwards, the central portions of the substrate will approach the bake plate at a point earlier in time than the peripheral portions. Accordingly, a phase shift between the derivative curves will be observable and may be utilized in determining the substrate bending mode. One of ordinary skill in the art would recognize many variations, modifications, and alternatives.

It should be appreciated that the specific steps illustrated in FIG. 8 provide a particular method of determining the substrate bending mode according to an embodiment of the present invention. Other sequences of steps may also be performed according to alternative embodiments. For example, alternative embodiments of the present invention may perform the steps outlined above in a different order. Moreover, the individual steps illustrated in FIG. 8 may include multiple sub-steps that may be performed in various sequences as appropriate to the individual step. Furthermore, additional steps may be added or removed depending on the particular applications. One of ordinary skill in the art would recognize many variations, modifications, and alternatives.

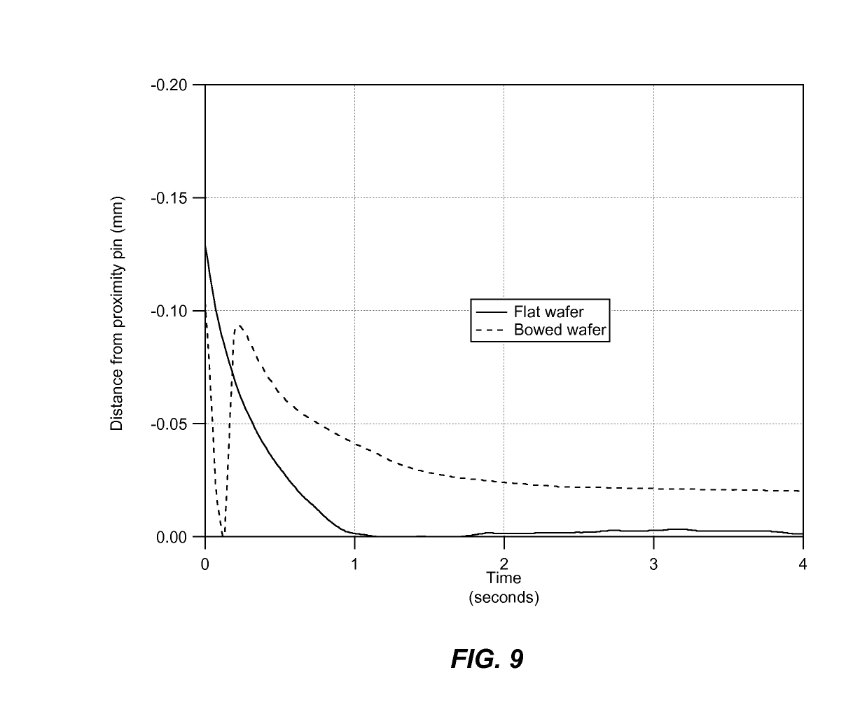

FIG. 9 is a plot of wafer distance versus time obtained using an embodiment of the present invention. FIG. 9 illustrates the settling times for a flat substrate and a bowed substrate measured at a single electrode. The data in FIG. 9 was collected for unchucked wafers. For the flat wafer, the distance between the wafer and the proximity pins decreases monotonically from about 0.12 mm to the contact position during the first second. A slight rebound is observed during the time period from about two seconds to four seconds.

For the bowed wafer, a rapid drop in distance is observed in approximately the first 120 ms, followed by an increase to the maximum distance at about 250 ms. Then, a slow decrease in distance is observed, with a tail extending to greater than four seconds. The tail for the bowed wafer is at a non-zero distance because the bow of the wafer separates the portion of the wafer adjacent the proximity pins from the proximity pins. As illustrated by the data presented in FIG. 9, utilizing the computed distances and/or derivatives as a function of time, embodiments of the present invention provide the capability to distinguish between various bending modes as described more fully throughout the present specification.

While the present invention has been described with respect to particular embodiments and specific examples thereof, it should be understood that other embodiments may fall within the spirit and scope of the invention. The scope of the invention should, therefore, be determined with reference to the appended claims along with their full scope of equivalents.

What is claimed is:

1. A method of performing a thermal process using a bake plate of a track lithography tool, wherein the bake plate includes a plurality of heater zones, the method comprising:
providing a first drive signal to a first electrode in electrical communication with a process surface of the bake plate, wherein the first electrode is associated with a first heater zone of the plurality of heater zones and each of the plurality of heater zones is adapted to receive a control voltage;
moving a semiconductor substrate toward the process surface of the bake plate;
receiving a first response signal from the first electrode;
processing the first response signal to determine a first capacitance value associated with a first gap between the first electrode and a first portion of the semiconductor substrate; and
providing a measurement signal related to the first capacitance value.

2. The method of claim 1 further comprising modifying a first control voltage for a first heater zone of the plurality of heater zones, the first control voltage being based, in part, on the measurement signal.

3. The method of claim 1 wherein the measurement signal comprises a gap distance signal.

4. The method of claim 1 further comprising:
providing a second drive signal to a second electrode in electrical communication with the process surface of the bake plate, wherein the second electrode is associated with a second heater zone of the plurality of heater zones;
receiving a second response signal from the second electrode;
processing the second response signal to determine a second capacitance associated with a second gap between the second electrode and a second portion of the semiconductor substrate; and
providing a second measurement signal related to the second capacitance value.

5. The method of claim 4 further comprising modifying a second control voltage for second heater zone of the plurality of heater zones, the second control voltage being based, in part, on the second measurement signal.

6. The method of claim 4 wherein:
a first heating element of the first heater zone comprises the first electrode; and
a second heating element of the second heater zone comprises the second electrode.

7. The method of claim 1 wherein the first portion of the semiconductor substrate is adjacent to the second portion of the semiconductor substrate.

8. The method of claim 1 wherein the first electrode spatially overlaps with at least a portion of the first heater zone.

9. The method of claim 1 wherein the drive signal comprises an oscillatory signal.

10. The method of claim 9 wherein the oscillatory signal is characterized by a frequency greater than or equal to 0.1 kHz.

11. The method of claim 1 wherein the first response signal is shifted in at least one of phase or amplitude with respect to the first drive signal.

12. The method of claim 1 wherein the first portion of the semiconductor substrate comprises an area of the semiconductor substrate opposing the first electrode.

13. The method of claim 1 further comprising:
providing a second drive signal to the first electrode, the second drive signal being based, in part, on the measurement signal.

14. The method of claim 13 wherein the second drive signal is operative to generate an electrostatic chucking force between the semiconductor substrate and the first electrode.

15. The method of claim 1 wherein the control voltage for each of the plurality of heater zones is operative to modify a temperature associated with each of the plurality of heater zones.

16. A bake plate system for a track lithography tool, the bake plate system comprising:
a processing system comprising:
a heater controller; and
a processor adapted to:
output a plurality of first drive signals in a first frequency range;
receive a plurality of response signals related to the plurality of first drive signals; and
output a plurality of second drive signals in a second frequency range; and
a bake plate comprising:
a process surface and a lower surface opposing the process surface;
a plurality of independent heating elements in thermal contact with the process surface, wherein each of the plurality of independent heating elements is adapted to receive a control signal from the heater controller;
a plurality of electrodes coupled to the process surface, wherein each of the plurality of electrodes is adapted to receive one of the plurality of first drive signals from the processor and one of the plurality of second drive signals from the processor; and
a plurality of mechanical stops disposed on the process surface.

17. The bake plate system of claim 16 wherein the plurality of independent heating elements and the plurality of electrodes share common components.

18. The bake plate system of claim 16 wherein the plurality of electrodes comprise:
a first set of pocket electrodes, each of the pocket electrodes being positioned adjacent to each of the plurality of mechanical stops; and
a second set of interior electrodes.

19. The bake plate system of claim 18 wherein the second set of interior electrodes comprises a center electrode and a plurality of peripheral electrodes positioned at a radial distance less than a radial distance associated with each of the pocket electrodes.

20. The bake plate system of claim 19 wherein the plurality of peripheral electrodes comprise four peripheral electrodes.

21. The bake plate system of claim 16 wherein each of the plurality of mechanical stops comprise a protrusion extending from the process surface of the bake plate, a radial distance from each of the plurality of mechanical stops to a centerpoint of the bake plate being greater than one half a substrate diameter.

22. The bake plate system of claim 16 wherein each of the plurality of electrodes comprise a conductive layer.

23. The bake plate system of claim 16 wherein the first frequency range comprises frequencies higher than about 0.1 kHz and the second frequency range comprises frequencies lower than about 0.1 kHz.
